(19) United States
(12) Patent Application Publication
(10) Pub. No.: US 2007/0223548 A1
(43) Pub. Date: Sep. 27, 2007

(54) Semiconductor laser device

(75) Inventors: Hiroki Ohbo, Tottori-city (JP); Yasuyuki Bessho, Uji-city (JP); Kazushi Mori, Osaka (JP); Yasuhiko Nomura, Osaka (JP)

Correspondence Address: NDQ&M WATCHSTONE LLP, 1300 EYE STREET, NW, SUITE 1000 WEST TOWER, WASHINGTON, DC, 20005, US

(73) Assignee: SANYO ELECTRIC CO., LTD., Moriguchi (JP)

(21) Appl. No.: 11/723,642

(22) Filed: Mar. 21, 2007

(30) Foreign Application Priority Data
Mar. 22, 2006 (JP) P2006-079513
Mar. 13, 2007 (JP) P2007-063354

(51) Int. Cl. H01S 5/00

(52) U.S. Cl. 372/44.01

(57) ABSTRACT

In a semiconductor laser device including a package for airtight sealing, and a semiconductor laser element provided in the package, a moisture concentration inside the package is 2500 ppm or less and arithmetic mean roughness in at least one portion of an inner surface of the package is 0.3 μm or less.

### CROSS REFERENCE TO RELATED APPLICATIONS

This application is based upon and claims the benefit of priority from prior Japanese Patent Application No. 2006-079513, filed on Mar. 22, 2006; and prior Japanese Patent Application No. 2007-63354, filed on Mar. 13, 2007; the entire contents of which are incorporated herein by reference.

### BACKGROUND OF THE INVENTION

1. Field of the Invention

The present invention relates to an air-tightly sealed semiconductor laser device.

2. Description of the Related Art

A semiconductor laser device provided with a semiconductor laser element in an air-tightly sealed package is well known. In such a semiconductor laser device, materials forming the semiconductor laser element and the like cause chemical changes by moisture contained in an atmosphere inside the package to deteriorate characteristics of the semiconductor laser element. For this reason, there is a problem that characteristics of the semiconductor laser device are deteriorated.

Moreover, a semiconductor laser device is known, which is capable of decreasing a moisture concentration (10⁵ ppm or less) inside a package by air-tightly sealing the package in a nitrogen atmosphere where a moisture concentration is decreased by heating or the like. Furthermore, a technique is known, which reduces a moisture concentration inside a package up to 5000 ppm or less.

### SUMMARY OF THE INVENTION

As a result of keen studies carried out by the inventor, et al. of the present application, it is found that a driving current for driving a semiconductor laser element greatly rises after being driven for a long time, in a semiconductor laser device where a moisture concentration inside a package is simply reduced.

According to an aspect of the present invention, a semiconductor laser device includes a package for airtight sealing and a semiconductor laser element provided inside the package. A moisture concentration inside the package is 2500 ppm or less, and arithmetic mean roughness in at least one portion of an inner surface of the package is 0.3 μm or less.

It is preferable that the arithmetic mean roughness in at least one portion of the inner surface of the package be 0.1 μm or less.

It is also preferable that the semiconductor laser element has a light-emitting layer including an AlGaInN-based semiconductor.

It is preferable that the semiconductor laser element is an element driven to have an output power of 50 mW or more.

### BRIEF DESCRIPTION OF THE DRAWINGS

FIG. 1 is a general structural view of a semiconductor laser device according to an embodiment of the present invention.

FIG. 2 is a schematic view of uneven portions in a predetermined region on a surface.

FIG. 3 is a schematic view of an electrolytic polishing process device.

FIG. 4 is a graph showing a relationship between a driving current rising rate and an arithmetic mean roughness of an inner surface of a cap in the semiconductor laser device.

FIG. 5 is a graph showing a relationship between a driving current rising rate and a moisture concentration inside a package in the semiconductor laser device.

FIG. 6 is a graph showing an increasing amount of a moisture concentration inside the package after being continuously energized in a relationship between an initial value of the moisture concentration inside the package and the arithmetic mean roughness of the inner surface of the cap.

FIG. 7 is a characteristic graph showing a relationship between an output power and a driving current rising rate after driving for 100 hours in the semiconductor laser device using a nitride-based semiconductor laser element with a wavelength of approximately 405 nm.

### DETAILED DESCRIPTION OF THE EMBODIMENTS

Embodiments of the present invention will be described below with reference to drawings.

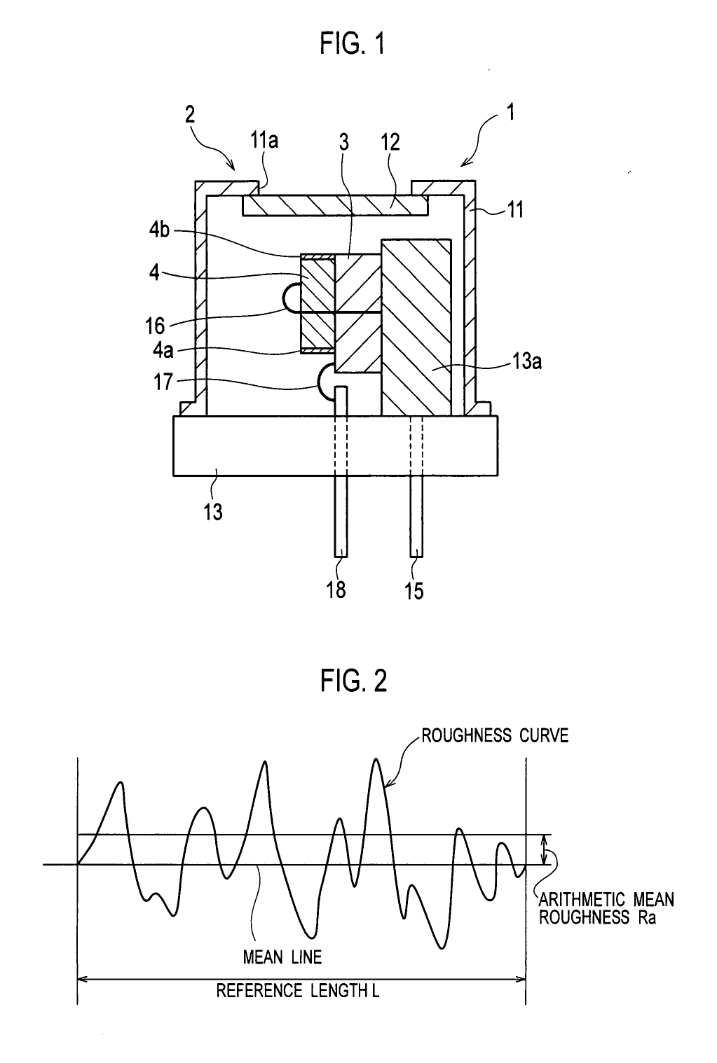

FIG. 1 is a general structural view of a semiconductor laser device according to an embodiment of the present invention.

As shown in FIG. 1, a semiconductor laser device 1 includes a package 2, a sub-mount 3, and a semiconductor laser element 4.

The package 2 includes a cap 11, a window member 12, and a stem 13.

The cap 11 is formed of kovar including Fe, Co, and Ni, and a surface thereof is plated with Ni/Au for antioxidation. An opening portion 11a is formed on an upper surface of the cap 11. Light emitted from the semiconductor laser element 4 is irradiated outside through the opening portion 11a. A window member 12 described later is provided so as to cover the opening portion 11a.

The cap 11 may be formed of alloys including Fe and Ni, and plated with Ni/Au for antioxidation. The cap 11 may be formed of glasses having low melting point (e.g. oxidation including Zn, Pb, Ti and B)

The window member 12 is formed of transparent material such as borosilicate glass, which transmits the light emitted from the semiconductor laser element 4.

The stem 13 has a protrusion portion 13a protruding inside the package 2 on an upper surface of the stem 13. The stem 13 is formed of Fe and Cu, and has the Fe—Cu—Fe structure (the structure where Cu is provided between Fe). A surface of the stem 13 is plated with Ni/Au for antioxidation.

The stem 13 may be simply formed of Fe. The stem 13 may be mainly formed of Fe, and a portion which functions as heat sink (the protrusion portion 13a) may be formed of Cu.

A lead pin 15 and a lead pin 18 are provided with the stem 13. The lead pin 15 and the lead pin 18 are formed of kovar including Fe, Co, and Ni. Surfaces of the lead pin 15 and the lead pin 18 are plated with Ni/Au for antioxidation.

The lead pin 15 and the lead pin 18 may be formed of alloy including Fe and Ni.

The upper surface of the stem 13 and the bottom surface of the cap 11 are adhered by welding or the like. Accordingly, the inside of the package 2 is air-tightly sealed by the cap 11 provided with the window member 12, and the stem 13.

Here, in the semiconductor laser device 1 of the present invention, the moisture concentration inside the package 2 is set to 2500 ppm or less. In addition, the inner surface of the cap 11 is formed to have the arithmetic mean roughness Ra of 0.3 μm or less, preferably 0.1 μm or less.

Here, the arithmetic mean roughness Ra will be described with reference to FIG. 2. FIG. 2 is a schematic view of uneven portions on the predetermined surface. The arithmetic mean roughness Ra is calculated based on the JIS B0601-1994 standard and JIS B0601-2001 standard, by use of a confocal laser scanning microscope (OLS 3000) manufactured by Olympus Corporation. Hereinafter, difference from these standards will be explained mainly.

(1) A height-noise reduction filter is applied to raw image acquired by the confocal laser scanning microscope. The height-noise reduction filter is a filter for correcting height data insufficiently acquired, by the height data sufficiently acquired, when the height data cannot be acquired sufficiently since reflected light from a sample is little.

(2) Consequently, a smoothing filter is applied to the raw image acquired by the confocal laser scanning microscope. The smoothing filter is a filter for correlating the height data of pixels where burst noise occurs with the height data of peripheral pixels of the pixels where the burst noise occurs, and smoothing the height data of pixels where the burst noise occurs, by the height data of the peripheral pixels, when the burst noise occurs. Note that the correlating and the smoothing are performed in unit of 5 pixels*5 pixels.

A method of calculating the arithmetic mean roughness Ra based on roughness curve which is the height data thus acquired, with reference to the FIG. 2.

As shown in FIG. 2, the roughness curve corresponding to a reference length L in the direction of a mean line of the roughness curve is extracted. The reference length L is a width of microscope field of the raw image acquired by the confocal laser scanning microscope. Consequently, the absolute value of deviations f(x) between the mean line and the roughness curve extracted are summed up, and then the sum of the absolute value of the deviations f(x) is averaged. Specifically, the arithmetic mean roughness Ra is calculated according to following formula.

$$Ra = \frac{1}{L} {\int }_{0}^{L} \vert f ( x ) \vert ⅆ x \qquad [ Formula 1 ]$$

As shown in FIG. 1, the sub-mount 3 is formed of AlN, and is provided in the protrusion portion 13a of the stem 13.

The semiconductor laser element 4 is not particularly limited, and The semiconductor laser element 4 may be a red semiconductor laser element, an infrared semiconductor laser element, and blue/blue-violet semiconductor laser element. In the present embodiment, a case will be described where a blue/blue-violet semiconductor laser element formed of a nitride semiconductor-based material is used as the semiconductor laser element 4. The semiconductor laser element 4 is provided on a side surface of the sub-mount 3 with a light outputting direction facing toward the window member 12. One side surface of the semiconductor laser element 4 is connected with a lead pin 15 through a wire 16 and a metal film (not shown) formed on the surface of the protrusion portion 13a of the stem 13. In addition, the other side surface of the semiconductor laser element 4 is connected with a lead pin 18 through a metal film (not shown) formed on the side surface of the sub-mount 3 and a wire 17. On a lower surface of the semiconductor laser element 4, an edge coating 4a on which five pairs of SiO₂/TiO₂ are laminated is formed, and on the upper surface of the semiconductor laser element 4, an edge coating 4b made of SiO₂ is formed by sputtering method.

In the above-described semiconductor laser device 1, when a voltage is applied between a pair of the lead pins 15 and 18, electrons and holes are injected to the semiconductor laser element 4. Thereby, a light emission occurs at an active layer (not shown) of the semiconductor laser element 4. The light emitted in the active layer is reflected between the edge coatings 4a and 4b. Then, a laser beam is irradiated from the edge coating 4b, and the laser beam is emitted through the window member 12.

Next, the steps of manufacturing the above-described semiconductor laser device will be described.

Firstly, the inner surface of the cap 11 is processed by pressing or cutting, and the arithmetic mean roughness Ra of the inner surface of the cap 11 is set to approximately 0.5 μm.

Next, in order to further minimize the arithmetic mean roughness Ra of the inner surface of the cap 11, a chemical polishing process is carried out. Specifically, the cap 11 is soaked in a chemical polishing solution so that the surface of kovar forming the cap 11 is uniformly corroded. Accordingly, uneven portions formed on the inside surface of the cap 11 are dissolved and smoothed. It should be noted that one of the examples used in the chemical polishing process including a chemical polishing solution, temperature setting, and processing time, is shown in table 1.

TABLE 2

| COMPOSITIONS OF CHEMICAL | | | PROCESS |
|---|---|---|---|
| POLISHING SOLUTION | | TEMPERATURE | TIME |
| (WEIGHT RATIO) | | (° C.) | (min) |
| PHOSPHORIC ACID | | 120 | 1˜2 |
| (CONDENSATION) | | | |
| OXALIC ACID | 25 | | SEVERAL |
| HYDROGEN PEROXIDE | 13 | | MINUTES |
| ACETIC ACID | 0.1 | 20˜30 | |
| WATER | 1 | | |

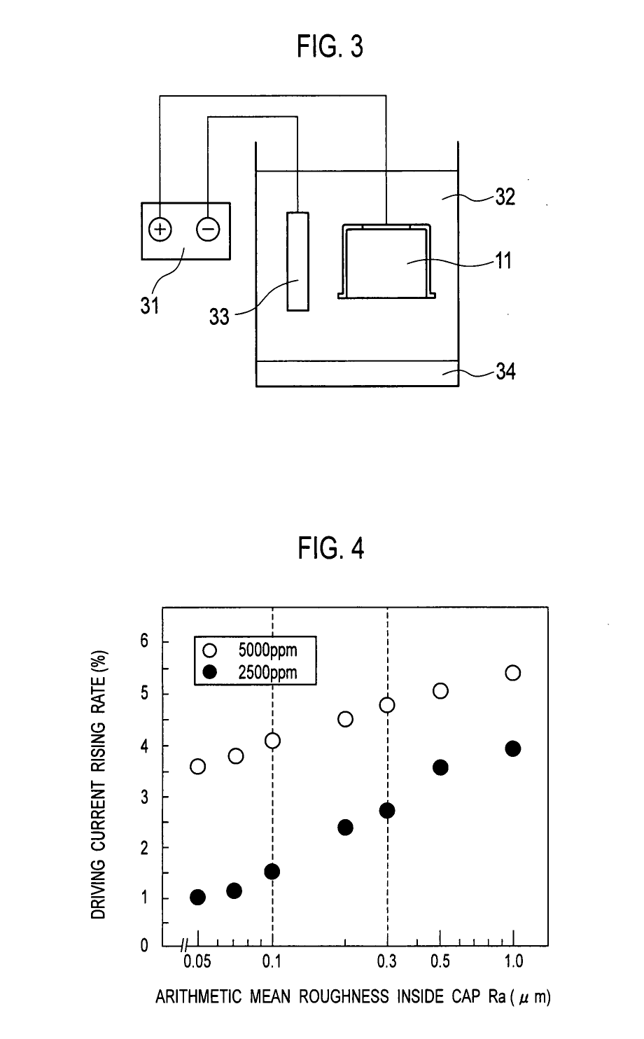

Next, in order to further minimize the arithmetic mean roughness Ra of the inner surface of the cap 11, an electrolytic polishing process is carried out. FIG. 3 is a schematic view of an electrolytic polishing process device. As shown in FIG. 3, in the electrolytic polishing process, the cap 11 that is connected to a direct current power source 31 and is soaked in an electrolytic polishing solution 32 is firstly set to an anode, and a cathode 33 that is connected to the direct current power source 31 and is soaked in the electrolytic polishing solution 32 is prepared. In this state, while the electrolytic polishing solution 32 is heated by a hot plate 34, a voltage is applied between the cap 11 and the cathode 33 by the direct current power source 31. As a result, the protrusion portion on the surface of the cap 11 is dissolved, and then the surface of the cap 11 becomes smoother than the surface of the cap 11 after the chemical polishing is performed. It should be noted that one of the examples of compositions used in an electrolytic polishing solution process including a flowing current density, a setting temperature, and a process time is shown in table 2.

TABLE 2

| COMPOSITIONS OF | | | | |
|---|---|---|---|---|
| ELECTROLYTIC | | | TEMPER- | PROCESS |
| POLISHING SOLUTION | | CURRENT | ATURE | TIME |
| (WEIGHT RATIO) | | DENSITY | (° C.) | (min) |
| PERCHLORIC ACID | 20 | 13˜40 | 20˜25 | 0.1˜0.2 |
| ETHYL ALCOHOL | 80 | | | |
| PERCHLORIC ACID | 20˜30 | 15˜30 | 20˜25 | 5˜15 |
| ACETIC ANHYDRIDE | 80˜70 | | | |
| PHOSPHORIC ACID | 55˜78 | | | |
| SULFURIC ACID | 12˜20 | 30˜100 | 30˜100 | 5˜20 |
| CHROMIC ACID | 5˜7 | | | |
| WATER | REST | | | |

It should be noted that the arithmetic mean roughness Ra of the inner surface of the cap 11 was observed and measured by using the confocal laser scanning microscope (OLS 3000) manufactured by Olympus Corporation.

Next, the cap 11 where the window member 12 is fixed, and the stem 13 where the sub-mount 3 and the semiconductor laser element 4 is fixed by soldering, are inserted into an air-tightly sealed chamber. In this state, nitrogen (N₂) is continuously purged in the sealed chamber for 12 hours or more, so that the moisture concentration of an atmosphere inside the sealed chamber is reduced to approximately 4000 ppm. Next, inside the sealed chamber where the cap 11 and the stem 13 are installed is baked with a temperature of approximately 200° C. for 30 minutes or more, so that the moisture concentration of the atmosphere inside the sealed chamber is reduced to approximately 2500 ppm or less. In this state, the cap 11 is welded to the stem 13. As a result, the semiconductor laser device 1 shown in FIG. 1 is completed. It should be noted that the moisture concentration inside the package 2 was measured by measuring a gas released from the inside the package 2 by using a quadrupole mass spectrometer (QMG421C) manufactured by Balzers GmbH, Germany after breaking the once-welded semiconductor laser device 1 in a vacuum.

In the semiconductor laser device 1 of the present embodiment, as described above, the moisture concentration inside the package 2 is set to approximately 2500 ppm or less and the arithmetic mean roughness Ra of the inner surface of the cap 11 is set to approximately 0.3 μm or less, preferably approximately 0.1 μm. As a result, it is possible to reduce the rise of driving current due to moisture inside the package 2, and heat generation according to the rise of driving current, caused by driving the semiconductor laser element 4 for a long time. Therefore, the semiconductor laser device 1 can be provided, which has stable and preferable characteristics even after driving for a long time.

Furthermore, even if the temperature inside the package 2 becomes low after the drive of the semiconductor laser element 4 is stopped, the condensation of the moisture on the window member 12 can be suppressed.

### EXAMPLES

Experiments that were carried out to prove the effects of the above-described semiconductor laser device of the present invention will be described below. It should be noted that a semiconductor laser element formed of a nitride-based semiconductor with a light-emitting wavelength of approximately 405 nm was used as a semiconductor laser element.

Firstly, two types of the semiconductor laser device 1, each having a different arithmetic mean roughness Ra of an inner surface of a cap 11, were prepared. Specifically, the semiconductor laser device 1 according to the present invention was prepared, where the moisture concentration inside the package 2 was set to approximately 2500 ppm and a semiconductor laser device 1 for comparison was prepared, where a moisture concentration inside a package 2 was set to approximately 5000 ppm. Each of the prepared semiconductor laser devices 1 was driven to have output power of 50 mW for 100 hours with a temperature set to 70° C. Then, a rising rate (%) of driving current after driving for 100 hours to driving current at 0 hour was measured. The results are shown in FIG. 4. It should be noted that in FIG. 4, white circles show experimental results of the semiconductor laser device 1 where the moisture concentration inside the package 2 was set to approximately 5000 ppm, while black circles show experimental results of the semiconductor laser device 1 where the moisture concentration inside the package 2 was set to approximately 2500 ppm.

As shown in FIG. 4, it is found that the rising rate of driving current in the semiconductor laser device 1 where the moisture concentration inside the package 2 was set to approximately 2500 ppm was smaller than the rising rate of driving current in the semiconductor laser device 1 where the moisture concentration was set to approximately 5000 ppm. In particular, in a case where the arithmetic mean roughness Ra of the inner surface of the cap 11 was set to approximately 0.3 μm or less, it is found that the rising rate of driving current in the semiconductor laser device 1 where the moisture concentration was set to approximately 2500 ppm was smaller than the rising rate of driving current in the semiconductor laser device 1 where the moisture concentration was set to approximately 5000 ppm.

For example, in a case where the arithmetic mean roughness Ra of the inner surface of the cap 11 was set to approximately 1.0 μm, the rising rate (approximately 5.4%) of driving current in the semiconductor laser device 1 where the moisture concentration was set to approximately 5000 ppm was approximately 1.4 times larger than the rising rate (approximately 3.9%) of driving current in the semiconductor laser device 1 where the moisture concentration was set to approximately 2500 ppm.

On the other hand, in a case where the arithmetic mean roughness Ra of the inner surface of the cap 11 was set to approximately 0.3 μm, the rising rate (approximately 4.8%) of driving current in the semiconductor laser device 1 where the moisture concentration was set to approximately 5000 ppm was approximately 1.8 times larger than the rising rate (approximately 2.7%) of the driving current in the semiconductor laser device 1 where the moisture concentration was set to approximately 2500 ppm.

Furthermore, in a case where the arithmetic mean roughness Ra of the inner surface of the cap 11 was set to approximately 0.1 μm, the rising rate (approximately 4.1%) of driving current in the semiconductor laser device 1 where the moisture concentration was set to approximately 5000 ppm was approximately 2.7 times larger than the rising rate (approximately 1.5%) of driving current in the semiconductor laser device 1 where the moisture concentration was set to approximately 2500 ppm.

As a result, it is found that compared with the semiconductor laser device 1 where the moisture concentration inside the package 2 was set to approximately 5000 ppm, the semiconductor laser device 1 where the moisture concentration inside the package 2 was set to approximately 2500 ppm had a smaller rising rate of driving current, in a case where the arithmetic mean roughness Ra of the inner surface of the cap 11 was set to approximately 1.0 μm. In addition, it is found that a reducing rate of the rising rate of driving current is larger, in a case where the arithmetic mean roughness Ra of the inner surface of the cap 11 was set small.

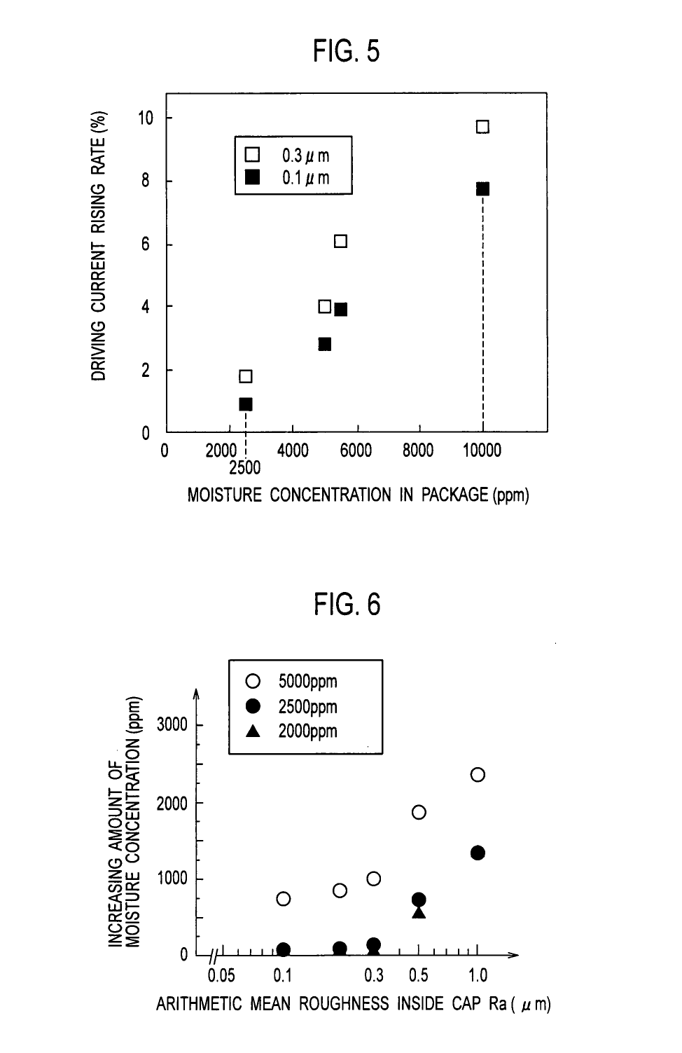

Next, a semiconductor laser device 1 of the present invention where the arithmetic mean roughness Ra of the inner surface of the cap 11 was set to approximately 0.3 μm and a semiconductor laser device 1 where arithmetic mean roughness Ra of the inner surface of the cap 11 was set to approximately 0.1 μm were prepared, each having a different moisture concentration inside a package 2 respectively. Each of the semiconductor laser devices 1 was driven to have output power of 50 mW for 300 hours with a temperature set to 70° C. Then, a rising rate (%) of driving current after driving 300 hours to driving current at 0 hour was measured. The results are shown in FIG. 5. It should be noted that in FIG. 5, white squares show experimental results of the semiconductor laser device 1 where the arithmetic mean roughness Ra of the inner surface of the cap 11 was set to approximately 0.3 μm, while black squares show experimental results of the semiconductor laser device 1 where the arithmetic mean roughness Ra of the inner surface of the cap 11 was set to approximately 0.1 μm.

As shown in FIG. 5, it is found that even when the semiconductor laser element 4 was driven for 300 hours, the rising rate of driving current in the semiconductor laser device 1 where the arithmetic mean roughness Ra of the inner surface of the cap 11 was set to approximately 0.1 μm was smaller than the rising rate of driving current in the semiconductor laser device 1 where the arithmetic mean roughness Ra of the inner surface of the cap 11 was set to approximately 0.3 μm. In particular, it is also found that a difference between the rising rates of the driving currents becomes remarkable in a case where the moisture concentration inside the package 2 is low.

For example, in a case where the moisture concentration inside the package 2 was set to approximately 10000 ppm, the rising rate (approximately 9.7%) of driving current in the semiconductor laser device 1 where the arithmetic mean roughness Ra of the inner surface of the cap 11 was set to approximately 0.3 μm became approximately 1.3 times larger than the rising rate (approximately 7.7%) of driving current of the semiconductor laser device 1 where the arithmetic mean roughness Ra of the inner surface of the cap 11 was set to approximately 0.1 μm.

On the other hand, in a case of the semiconductor laser device 1 of the present invention where the moisture concentration inside the package 2 was set to approximately 2500 ppm, the rising rate (approximately 1.8%) of driving current in the semiconductor laser device 1 where the arithmetic mean roughness Ra of the inner surface of the cap 11 being approximately 0.3 μm became approximately 2.0 times larger than the rising rate (approximately 0.9%) of driving current in the semiconductor laser device 1 where the arithmetic mean roughness Ra of the inner surface of the cap 11 was set to approximately 0.1 μm.

As a result, it is found that the semiconductor laser device 1 where the moisture concentration inside the package 2 was set low (approximately 2500 ppm) like the present invention has a larger effect of reducing a rising rate of driving current by setting the arithmetic mean roughness Ra of the inner surface of the cap 11 small.

Hereinafter, examined were reasons why a rising rate of driving current in a semiconductor laser device 1 can be suppressed by setting a moisture concentration inside a package 2 to approximately 2500 ppm or less and arithmetic mean roughness Ra of an inner surface of a cap 11 to 0.3 μm or less.

Table 3 shows an increasing amount of a moisture concentration inside the package 2 after continuous current (70° C., 50 mW×300 hours) in a relationship between an initial value of the moisture concentration inside the package 2 and the arithmetic mean roughness Ra of the inner surface of the cap 11.

TABLE 3

| | ARITHMETIC MEAN ROUGHNESS (μm) | | | | |
|---|---|---|---|---|---|
| | 0.1 | 0.2 | 0.3 | 0.5 | 1.0 |
| INITIAL VALUE OF | 750 | 875 | 1000 | 1800 | 2300 |
| MOISTURE | | | | | |
| CONCENTRATION = | | | | | |
| 5000 ppm | | | | | |
| INITIAL VALUE OF | 75 | 100 | 150 | 750 | 1300 |
| MOISTURE | | | | | |
| CONCENTRATION = | | | | | |
| 2500 ppm | | | | | |
| INITIAL VALUE OF | 50 | — | 75 | 550 | — |
| MOISTURE | | | | | |
| CONCENTRATION = | | | | | |
| 2000 ppm | | | | | |

FIG. 6 is a graph in which values shown in table 3 are plotted on coordinates. It should be noted that in FIG. 6, the vertical axis shows the increasing amount of the moisture concentration after the continuous current, and the horizontal axis shows arithmetic mean roughness Ra of the inner surface of the cap 11.

As shown in table 3 and FIG. 6, in a case where the initial value of the moisture concentration inside the package 2 was 5000 ppm, the increasing amount of the moisture concentration after continuous current became 750 ppm or more even when the arithmetic mean roughness Ra is set to small.

On the contrary, in a case where the initial value of the moisture concentration inside the package 2 was 2500 ppm, the increasing amount of the moisture concentration after continuous current became 150 ppm or less if the arithmetic mean roughness Ra was set to 0.3 μm or less.

Similarly, in a case where the initial value of the moisture concentration inside the package 2 was 2000 ppm, the increasing amount of the moisture concentration after continuous current became 75 ppm or less if the arithmetic mean roughness Ra was set to 0.3 μm or less.

In this manner, it was confirmed that the increasing amount of the moisture concentration after continuous current was suppressed by setting the initial value of the moisture concentration inside the package 2 to approximately 2500 ppm or less and setting the arithmetic mean roughness Ra of the inner surface of the cap 11 to 0.3 μm or less.

As shown in FIGS. 4 and 5, the rising rate of driving current of the semiconductor laser device 1 was suppressed by setting the initial value of the moisture concentration inside the package 2 to approximately 2500 ppm or less and the arithmetic mean roughness Ra of the inner surface of the cap 11 to 0.3 μm or less. This is because the increasing amount of the moisture concentration after continuous current is suppressed as shown in table 3 and FIG. 6.

Moreover, it was confirmed that it is preferable to set the initial value of the moisture concentration inside the package 2 to approximately 2000 ppm or less and the arithmetic mean roughness Ra of the inner surface of the cap 11 to 0.1 μm or less. Accordingly, since the moisture concentration inside the package 2 is low and the increasing amount of the moisture after continuous current is sufficiently suppressed, the rising of driving current after continuous current is suppressed. Additionally, since the rising of driving current after continuous current is sufficiently suppressed, further improvement in reliability of the semiconductor laser element is achieved.

On the other hand, even in a conventional technology, it has been well known that a semiconductor laser element is sealed inside a package by setting a moisture concentration lower. However, the conventional technology only focuses on a moisture concentration inside a package at the time of sealing a semiconductor laser element inside the package.

Here, moisture put on the inner surface of each constituent member forming the package such as a cap, a stem or the like does not contribute to the moisture concentration inside the package at the time of sealing a semiconductor laser element inside the package. On the other hand, in practice, due to heat generated by driving the semiconductor laser element, the moisture put on the inner surface of the package is released inside the package. Accordingly, it is considered that in association with driving the semiconductor laser element, the moisture concentration inside the package is increased and the semiconductor laser element is deteriorated.

Therefore, in the present invention, not only a moisture concentration at the time of sealing a semiconductor laser element inside a package but also an arithmetic mean roughness Ra of the inner surface of the package is noted. Specifically, in the present invention, by setting the arithmetic mean roughness Ra of the inner surface of the package small, moisture put on the inner surface of the package 2 is reduced, which does not contribute to the moisture concentration inside the package 2 when the semiconductor leaser element 4 is sealed inside the package 2. Thereby, it is considered that even when the semiconductor laser element 4 is driven for a long time, the increase of the moisture concentration inside the package, and the deterioration of the semiconductor laser element 4 can be suppressed.

More specifically, in the present invention, the moisture concentration inside the package 2 is set to approximately 2500 ppm or less and the arithmetic mean roughness Ra of the inner surface of the cap 11 is set to approximately 0.3 μm or less. Thus, according to the present invention, it is possible to increase the effect of reducing the rising rate of driving current, even though the driving current rises due to the adverse affect of moisture in the semiconductor laser element 4. Accordingly, it is possible to provide the semiconductor laser device 1 that maintains characteristics thereof stably for a long time.

It should be noted that in the above-described embodiment, the semiconductor laser device 1 using a blue/blue-violet semiconductor laser element as a semiconductor laser element 4 was explained. However, the present invention is not limited to this, and same effects can be obtained by using a semiconductor laser device using a semiconductor laser element having different light-emitting wavelength, such as a red semiconductor laser element, an infrared semiconductor laser element or the like.

Moreover, among other semiconductor laser elements having various kinds of light-emitting wavelength, the present invention is remarkably effective when a semiconductor element with a short light-emitting wavelength is used in a semiconductor laser device.

Three kinds of semiconductor laser elements were prepared. Specifically, an infrared semiconductor laser element with a light-emitting wavelength of approximately 780 nm, a red semiconductor laser element with a light-emitting wavelength of approximately 660 nm, and a blue-violet semiconductor laser element with a light-emitting wavelength of approximately 405 nm were prepared. Then, a semiconductor laser device was made respectively. Here, the infrared semiconductor laser element with a light-emitting wavelength in the band of 780 nm was prepared so as to have a light-emitting layer including an AlGaAs-based semiconductor. The red semiconductor laser element with a light-emitting wavelength in the band of 660 nm was prepared so as to have a light-emitting layer including an AlGaInP-based semiconductor. The blue/blue-violet semiconductor laser element with a light-emitting wavelength in the band of 400 nm was prepared so as to have a light-emitting layer including an AlGaInN-based semiconductor. Then, each of the semiconductor laser devices was examined in terms of a reducing ratio of the rising rate of driving current under first conditions to the rising rate of driving current under second conditions. The first conditions are that the moisture concentration was approximately 2500 ppm, and that the arithmetic mean roughness Ra of the inner surface of the cap was approximately 0.3 μm. The second conditions are that the moisture concentration was approximately 10000 ppm, and that the arithmetic mean roughness Ra of the inner surface of the cap was approximately 0.5 μm. As a result, the reducing ratio between the rising rates of driving current in the infrared semiconductor laser device, the red semiconductor laser device, and the blue-violet semiconductor laser device were approximately 28.6%, 33.3% and 60.0%, respectively. As described above, the effects of the present invention become larger as the light-emitting wavelength of the semiconductor laser element becomes shorter. In particular, in the semiconductor laser device using the semiconductor laser element with a light-emitting wavelength of approximately 405 nm, the reducing ratio between the rising rates of driving current could be reduced to 60%, that is, less than half. Accordingly, the present invention is particularly effective for the semiconductor laser device using the blue/blue-violet semiconductor laser element with a light-emitting layer including an AlGaInN-based semiconductor.

In addition, the semiconductor laser device in the band of 400 nm (in particular, with wavelengths between 400 nm and 410 nm) using the blue/blue-violet semiconductor laser element having the light-emitting layer including the AlGaInN-based semiconductor has been examined for recording or reproducing the data, the data stored in large capacity storage such as optical disks for HD DVD and Blu-ray disks or the like. When the application to these large capacity storage is considered, higher output power more than ever is required for semiconductor laser devices.

For example, in the Blu-ray standard, optical outputs of approximately 50 mW, 70 mW, and 100 mW are required for 1× speed recording, 2× speed recording and 4× speed recording, respectively.

On the other hand, in the HD DVD standard, to achieve the same recording density, an optical output that is approximately 2 to 2.6 times lager than that in the Blu-ray standard is generally required. Specifically, optical outputs of 100 mW to 130 mW, 140 mW to 180 mW, and 200 mW to 260 mW are required for 1× speed recording, 2× speed recording and 4× speed recording, respectively.

Then, as a recording/reproducing speed becomes faster and a recording density becomes larger, the optical output required for the semiconductor laser device becomes larger.

Furthermore, the semiconductor laser device in the band of 400 nm (in particular, with light-emitting wavelengths between 430 nm and 480 nm) using the blue/blue-violet semiconductor laser element having a light-emitting layer including the AlGaInN-based semiconductor has also been examined to be applied to a light source for display. In this application, the optical output of preferably 200 mW or more is required for the semiconductor laser device, and more preferably an extremely high optical output of 1 W to 3 W is required.

Then, as the required optical output becomes higher, adverse effects by the above-described rise of driving current become larger. Therefore, the demand for reducing the rising rate of driving current becomes increasingly large.

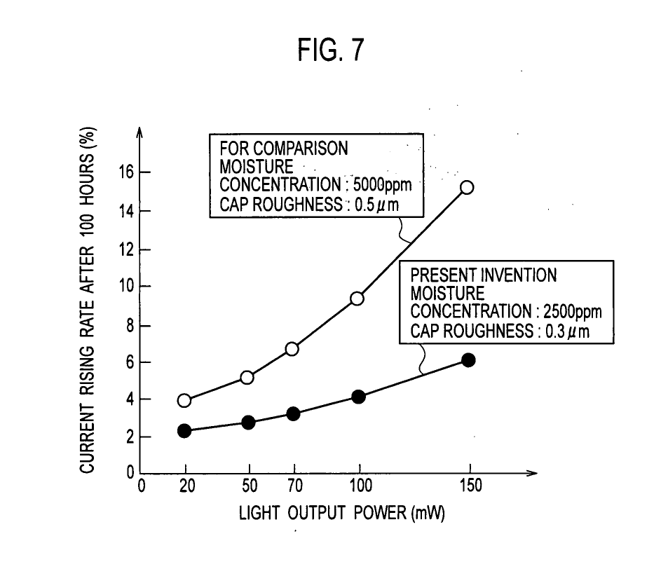

FIG. 7 is a characteristic graph showing a relationship between an output power and a driving current rising rate after driving for 100 hours in the semiconductor laser device using a nitride-based semiconductor laser element with a light-emitting wavelength of approximately 405 nm. Black circles in the figure show the rising rate of driving current in the semiconductor laser device of the present invention where the moisture concentration inside the package was set to approximately 2500 ppm and the arithmetic mean roughness Ra of the inner surface of the cap was set to approximately 0.3 μm. While white circles show the rising rate of driving current in the semiconductor laser device where the moisture concentration inside the package was set to approximately 5000 ppm and the arithmetic mean roughness Ra of the inner surface of the cap was set to approximately 0.5 μm.

As shown in FIG. 7, according to the present invention, it is found that the rising rate of driving current after driving for 100 hours can be reduced by approximately 6% or less even with the output of 150 mW. On the contrary, in the semiconductor laser device made for comparison, it is found that the increasing rate of the rising rate of driving current in relation to the increase of the optical output power became larger than that of the present invention, and the rising rate of driving current with the output of 150 mW becomes approximately 15%, which was approximately 3 times larger than that of the present invention.

As mentioned above, the present invention is particularly effective for blue/blue-violet semiconductor laser devices, which requires 50 mW or more output power, used for recording and reproducing in the large capacity storage, such as HD DVD, Blu-ray or the like, in the future.

Furthermore, the present invention is more effective for semiconductor laser devices used as a light source for display, which requires the optical output power of 200 mW or more.

### Other Embodiments

The present invention has been described by using the above-described embodiments, but it is apparent for those skilled in the art that the present invention is not limited to the embodiments described in the present specification.

The present invention can be implemented as a revised and modified embodiment without departing from the spirit and scope of the present invention as defined in the claims. Accordingly, the aim of the description of this specification is merely to describe the present invention for illustration and is not intended to limit the present invention. And now, partially modified embodiments of the above-described embodiments are described below.

For example, the material or the like forming the above-described cap 11 can be changed accordingly. Then, in a case where the material of the cap 11 is changed, it is desirable that the method of chemical polishing process, electrolytic polishing process or the like be changed accordingly. In addition, in the steps of manufacturing the above-described embodiments, both the chemical polishing process and the electrolytic polishing process were carried out, but in a case where the arithmetic mean roughness Ra on the surface is set to 0.1 μm or more, any one of these processes can be used.

In the above-described embodiments, the case is described that the arithmetic mean roughness Ra of the inner surface of the cap 11 is set to 0.3 μm or less, but it is not limited to this case. Specifically, the arithmetic mean roughness Ra of surface exposed inside space of the package where the semiconductor laser element is disposed may be set to 0.3 μm or less. In such case, the arithmetic mean roughness Ra of total or part of surface exposed inside space of the package may be set to 0.3 μm or less. For example, the arithmetic mean roughness Ra of entire inner surface of the package including the stem may be set to 0.3 μm or less.

In the above-described embodiments, baking of the sealed chamber was carried out for reducing the moisture concentration, but the moisture concentration may be reduced by irradiating an ultraviolet ray with the cap 11 on which the window member 12 is fixed, and the stem 13 in which the sub-mount 3 and the semiconductor laser element 4 are fixed by soldering. For example, the moisture concentration can be reduced by irradiating ultraviolet ray by a mercury lamp in an air or an oxygen atmosphere with a temperature of 100° C. for 30 minutes.

In a case where the semiconductor laser element 4 is fixed to the sub-mount 3 by an adhesive substance, the adhesive substance can be dissolved and removed by irradiating ultraviolet ray. Accordingly, moisture contained in the adhesive substance can be removed, so that the rise of moisture concentration in association with the temperature rise in the package 2 can be suppressed. Furthermore, since a material contained in the adhesive substance can suppress chemical reaction by blue-violet light irradiated from the semiconductor laser element 4, element deterioration of the semiconductor laser element 4 can be further suppressed. It should be noted that both baking and ultraviolet irradiation may be carried out in the sealed chamber.

In addition, the edge coating 4b is formed of SiO₂ in the above-described embodiments. But it is not limited to this, and a single layer film formed of dielectric films such as Nb₂O₅, Ta₂O₅, BN, MgF₂, CaF₂, TiO₂, Al₂O₃, ZrO₂, AlN, and SiN, or a multilayer film formed by selecting a plurality of materials from these materials, such as SiO₂/TiO₂ (SiO₂ on the element side) and SiO₂/AlN (SiO₂ on the element side) may be used.

The semiconductor laser element 4 of the above-described embodiment preferably has a light-emitting layer including AlGaInN-based semiconductor. In such case, the semiconductor laser element oscillates light with blue/blue-violet wavelengths between 380 nm and 480 nm. Here, the AlGaInN-based semiconductor means a semiconductor including N and at least any one of Al, Ga, and In elements, and a semiconductor including AlGaInN, GaInN, AlInN, AlGaN, AlN, GaN, and InN. In particular, it is preferable to have a light-emitting layer formed of a semiconductor including In.

What is claimed is:

1. A semiconductor laser device comprising a package for airtight sealing, and a semiconductor laser element provided in the package, wherein
a moisture concentration inside the package is 2500 ppm or less; and
arithmetic mean roughness in at least one portion of an inner surface of the package is 0.3 μm or less.

2. The semiconductor laser device according to claim 1, wherein the arithmetic mean roughness in at least one portion of the inner surface of the package is 0.1 μm or less.

3. The semiconductor laser device according to claim 1, wherein the semiconductor laser element has a light-emitting layer including an AlGaInN-based semiconductor.

4. The semiconductor laser device according to claim 3, wherein the semiconductor laser element is driven to have an output power of 50 mW or more.
